(19) United States
(12) Patent Application Publication
(10) Pub. No.: US 2010/0201393 A1
(43) Pub. Date: Aug. 12, 2010

(54) CHIP CARD WITH A MEASURING CIRCUIT THAT HAS A SENSOR, AND METHOD OF MAKING THE CHIP CARD

(75) Inventors: Victorio Quercia, Vallamand (CH); Michel Willemin, Preles (CH)

Correspondence Address: GRIFFIN & SZIPL, PC, SUITE PH-1, 2300 NINTH STREET, SOUTH, ARLINGTON, VA, 22204, US

(73) Assignee: EM MICROELECTRONIC-MARIN S.A., Marin (CH)

(21) Appl. No.: 12/699,335

(22) Filed: Feb. 3, 2010

(30) Foreign Application Priority Data
Feb. 10, 2009 (EP) EP 09152487.6

(51) Int. Cl. G01R 31/02

(52) U.S. Cl. 324/763

(57) ABSTRACT

The chip card (11) includes at least one integrated circuit (11) fitted with a memory unit, in which personal data and/or at least one chip card identification code and/or configuration parameters can be stored. The integrated circuit is enclosed in an insulating material (3) that forms said card. The chip card (1) also includes connecting means (2) for communicating with an electronic instrument. These connecting means are electrically connected to corresponding contact pads of the integrated circuit. The chip card further includes a measuring circuit with a sensor for measuring a physical parameter so as to provide at least one output signal relating to the measurement (S_{D}) of the physical parameter. The measuring circuit containing a sensor is arranged in a rigid case to define an electronic module (10), which is enclosed in the insulating material (3) that forms said chip card. The measuring circuit includes a movement sensor (C) for detecting a shock or for measuring an acceleration, and a sensor interface connected to the sensor for supplying a physical parameter measurement signal. The measuring circuit is electrically connected through the module case to external connection terminals on the case.

This application claims priority from European Patent Application No. 09152487.6 filed Feb. 10, 2009, the entire disclosure of which is incorporated herein by reference.

### FIELD OF THE INVENTION

The invention concerns a chip card fitted with a measuring circuit that has a sensor. The chip card may be a SIM card, which includes at least one integrated circuit provided with a memory unit, in which personal data and/or at least one chip card identification code and/or configuration parameters can be stored, and a measuring circuit with a sensor. The integrated circuit and the measuring circuit with a sensor are encapsulated in an insulating material that forms said card. The chip card also includes connecting means for communicating with an electronic instrument in which said chip card could, for example, be placed. These connecting means are electrically connected to corresponding contact pads of the integrated circuit.

The invention also concerns a method of making a chip card fitted with a measuring circuit that has a sensor.

“Connecting means” essentially means any means for communicating data and/or commands with an electronic instrument. These connecting means may be, for example, a zone of accessible electric contacts on at least one surface of the chip card. The electric contacts of said contact zone will come into contact with complementary contact terminals of an electronic instrument, in which said chip card can be placed.

### BACKGROUND OF THE INVENTION

The chip card may be, for example, a SIM card or a memory card or a credit card in a format that enables said cards to be placed in an electronic instrument, which may be, for example, a mobile (cellular) phone. In the case of a telecommunications instrument such as a mobile telephone, this chip card may preferably be a SIM card, which is adapted for insertion into a housing provided for that purpose inside said telephone and connected to contact terminals of the telephone. In a GSM cellular network, the use of this chip card in the electronic instrument, particularly in a mobile telephone, ensures user identification via a telecommunications system operator. This chip card also ensures the compatibility and interchangeability of mobile telephones within this telecommunications system.

These chip cards enable the user to access the mobile telecommunications system via an appropriate network provider or operator. They therefore include data, which defines the modes of access to the mobile telecommunications system and also allow storage of complementary data relating to the user. This complementary data concerns, for example, a personal identification number and/or a directory of telephone numbers.

The dimensions and physical features of each SIM (subscriber identity module) chip card are defined by international standards, such as, in particular, ISO/IEC standards 7810, 7816-1 and 7816-2. This type of chip card thus takes the form of a plastic card that houses at least one integrated circuit. There are two standard chip card formats for integration into a portable electronic instrument. The first format is comparable to that of a credit card (85.60 mm×53.98 mm×0.80 mm). The dimensions of the second format are smaller, around 25 mm×15 mm×0.8 mm, like the example illustrated in FIG. 1 and described in the following description.

It is also known to fit this type of SIM chip card with electronic means, such as an RFID device for two-directional data communication via an antenna of the RFID device, which is housed in the chip card. US Patent No. 2007/0281549, which mentions this RFID function in connection with said chip card integrated circuit can be cited in this regard. However, this type of RFID device only has similar functions to those related to telephony.

This type of chip card may also include other integrated electronic components in the insulating material of the chip card. These electronic components may be measuring circuits with a sensor, such as circuits for measuring a temperature in conjunction with the integrated circuit of said chip card. However, no precaution is specifically taken for integrating these conventional electronic components in the plastic material of the card with the integrated circuit.

It is also known from DE Patent No 297 17 395 U1 to integrate an electronic module, fitted with a measuring circuit that has a sensor, into a chip card in credit card format in order to perform a check for the transport of merchandise. However, again, no particular precaution is specified for the integration of a measuring circuit with a movement sensor without any damage.

Movement sensors may also be used in mobile telephones as described in US Patent No. 2008/0014989 and WO Patent No. 2004/082248. These movement sensors may be used for controlling some functions that the user has pre-programmed in the telephone, but they are not provided for direct integration into a chip card.

### SUMMARY OF THE INVENTION

It is therefore an object of the invention to provide a chip card that includes a measuring circuit with a sensor for overcoming the aforementioned drawbacks, and which thus avoids damaging the functionality of the measuring circuit integrated in the card.

The invention thus concerns the chip card, SIM type chip card, which includes at least one integrated circuit fitted with a memory unit, in which personal data and/or at least one chip card identification code and/or configuration parameters can be stored, wherein said integrated circuit is enclosed in an insulating material forming said card, the card also including connecting means for communicating with an electronic instrument in the form of a mobile telephone, said connecting means being electrically connected to corresponding contact pads of the integrated circuit, the chip card further including a measuring circuit with a sensor for measuring a physical parameter so as to provide at least one output signal relating to the measurement of the physical parameter, said measuring circuit with a sensor being arranged in a rigid case to define an electronic module, which is enclosed in the insulating material forming said chip card, wherein the measuring circuit includes a movement sensor, housed in a large enough space inside the case to allow detection of a shock or to measure an acceleration, and a sensor interface connected to the sensor to supply a physical parameter measurement signal, the measuring circuit being electrically connected through the module case to external connection terminals on the case, and wherein the electronic module is electrically connected by the external connection terminals to the first integrated circuit of the chip card, the electronic module and the first integrated circuit being placed side by side in the insulating material of the chip card on a first surface of a printed circuit board.

Particular embodiments of the chip card are defined in the dependent claims 2 to 10.

One advantage of the chip card, such as a SIM card, is that, once inserted and connected inside a portable instrument, such as a mobile telephone, it can provide data and/or control signals on the basis of at least one measurement carried out by the measuring circuit with a sensor, which includes, in particular, a movement sensor.

Advantageously, the measuring circuit, which includes the movement sensor and a sensor interface, is mounted in a rigid case to define an electronic module. This ensures better mechanical insulation for the sensor, which may be a MEMS acceleration sensor. This facilitates assembly of the electronic module containing a measuring circuit in the chip card without any stress by the plastic material on the measuring circuit sensor.

With this type of movement sensor, such as an acceleration or shock sensor, a command can be supplied directly to the portable electronic instrument or via the integrated circuit of said card. This command relating to the detected movement allows the instrument to recognise actions or functions to be performed that the user has pre-programmed. For example, one may envisage a specific function being performed in the instrument by a single acceleration or shock or impulse imparted to the chip card or several shocks or impulses imparted in succession to the chip card.

Advantageously, with this measuring circuit that contains a movement sensor, one could also envisage supplying a digital output measuring signal, which can be stored in a dedicated register of the integrated circuit memory unit. This output signal can control the portable instrument for recognition of models, menus, movements by the instrument user, shocks experienced by the instrument, or for drawings. In order to do this, the measuring circuit with the sensor may be an accelerometer or pedometer that uses a measurement of a capacitive variation in the differential mounted capacitors of a capacitive sensor. This accelerometer may also be a triaxial accelerometer, which can supply commands to the portable instrument, for example for remotely actuating a mechanical machine, such as a robot or a vehicle.

One advantage of said chip card mounted in the portable instrument is that if the movement sensor is an accelerometer, the acceleration measurement can command the portable instrument to change, for example, from a low power or stand-by mode to normal operating mode.

If the chip card is a SIM card or memory card, all the parameters linked to the measuring circuit, particularly configuration parameters, can be stored. These configuration parameters may be personal to the user of said chip card. This means that the portable instrument, such as the mobile telephone, in which said chip card is placed, can be changed, while keeping all the parameters stored, and without having to repeat configuration each time the instrument is changed. These parameters can be stored in a memory that is directly provided in the measuring circuit or in the integrated circuit memory unit.

The chip card may advantageously include its own electric power means. These electric power means may include a solar cell or an energy accumulator or an RFID device for picking up radio-frequency signals.

The invention therefore also concerns a method of manufacturing a chip card, wherein the method includes the steps consisting in:
mounting and electrically connecting the electronic module, whose case contains the measuring circuit with a movement sensor, and the integrated circuit of the card on a first surface of a printed circuit board, and
encapsulating the electronic module and the integrated circuit in a layer of insulating material that forms said card while allowing means for connecting the chip card, which are electrically connected at least to the integrated circuit, to communicate with an electronic instrument.

Particular steps for making said chip card are defined in the dependent claims 12 and 13.

### BRIEF DESCRIPTION OF THE DRAWINGS

The objects, advantages and features of the chip card, and the method of manufacturing the same, will appear more clearly in the following non-limiting description of at least one embodiment illustrated by the drawings, in which:

FIG. 1 shows a top view of a chip card in the form of a SIM card according to the invention for a mobile telephone,

FIG. 2 shows the electronic components of the chip card according to the invention in a simplified manner, and

FIGS. 3a and 3b show, in a simplified manner, a top view and a side view of the integrated circuit and the measuring circuit mounted in one part of the chip card according to the invention.

### DETAILED DESCRIPTION OF THE INVENTION

In the following description, all those parts of the chip card, which are well known to those skilled in the art in this technical field, are related only in a simplified manner.

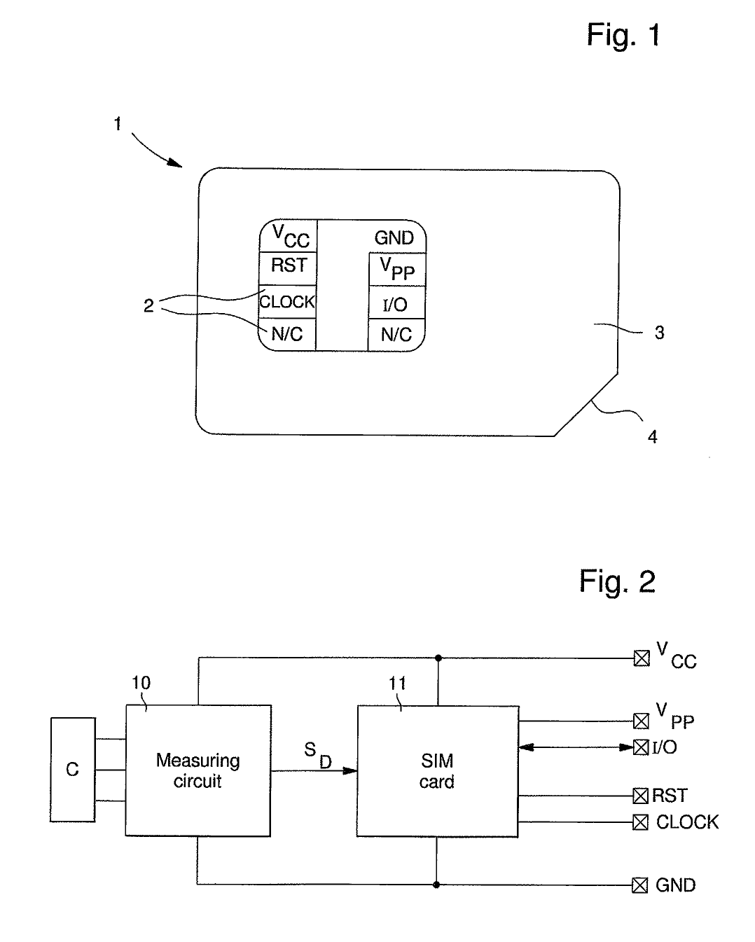

FIG. 1 shows a chip card or smart card in the form of a conventional SIM card 1. The main features of this SIM card 1, which may be used in a mobile telephone according to the present invention are thus briefly described.

This SIM card 1 takes the form of a flat, essentially rectangular element that has dimensions, for example, of the order of 15 mm×25 mm, and a thickness close to 0.76 mm. This SIM card 1 has, in particular, an oblique edge 4 used as a polarizing slot for orienting the card properly when it is inserted in a housing provided in the telephone for that purpose.

SIM card 1 also has connecting means 2 for communicating, in particular, data and/or commands to an electronic instrument, such as a mobile telephone in which said SIM card is placed. These connecting means may preferably be a zone of accessible electric contacts 2, which are arranged on at least one surface of said chip card. Electric contacts 2 are shown as being eight in number, but only six of these contacts are generally used. These electric contacts 2 are connected in a conventional manner to corresponding contact pads of an integrated circuit, which is not shown. This integrated circuit is thus enclosed in the opaque insulating material 3 that forms said chip card.

Electric contact zone 2 is arranged on one surface of the chip card in accordance with international standards as indicated above. Once the chip card has been inserted in the housing of a mobile telephone, the electric contacts of contact zone 2 are connected to complementary contact terminals provided in a well-defined position in the telephone. Electric power may be provided by the telephone to the chip card via two electric contacts V_{CC} and GND of contact zone 2. The following may also be provided: an electric contact RST for receiving a Reset signal, an electric contact V_{PP} for receiving a voltage signal for programming the memory unit, an electric contact CLOCK for receiving or providing a clock signal and an electric contact I/O for receiving or transferring data or commands.

As shown schematically in FIG. 2, said integrated circuit 11 for a SIM card generally has a memory unit (not shown), which is connected to a microprocessor unit (not shown) for processing received or transmitted data or commands. The memory unit may include a Flash or EEPROM non-volatile memory for storing personal data, at least one chip card identification code and configuration parameters. The memory unit also contains data defining access modes to the mobile telecommunications system.

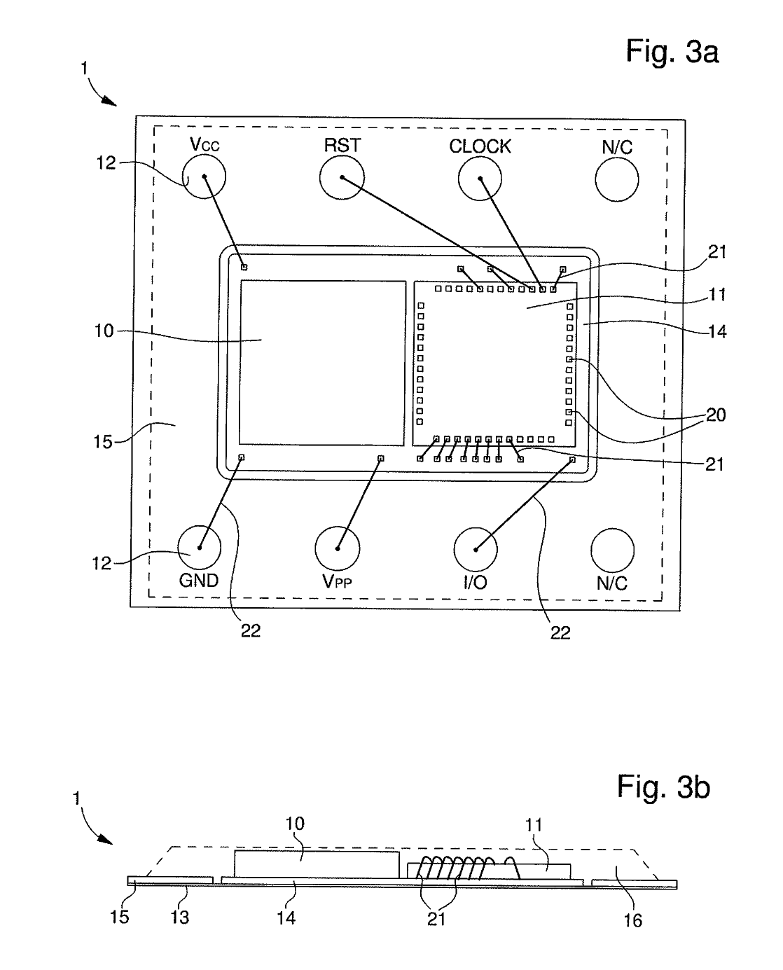

The chip card according to the invention also includes a measuring circuit 10 with a sensor C. As explained below with reference to FIGS. 3a and 3b, measuring circuit 10 with sensor C are housed in a rigid case to form an electronic module. The measuring circuit thus includes a sensor interface 10 and a MEMS type movement sensor C, which are connected across a lead frame made of copper inside the rigid case, which may be an MLF type plastic case. There is sufficient space inside the case for the movement sensor and the measuring circuit sensor interface to prevent any stress from the encapsulation material, which encloses said electronic module 10. The movement sensor can thus detect a shock or measure an acceleration without any problem. This electronic module containing a measuring circuit, which is preferably a single axis or triaxial accelerometer, or a pedometer, is also enclosed in the opaque insulating material forming said chip card.

One could envisage using an accelerometer, which has two differential mounted capacitors to form a capacitive sensor, whose capacitive variation is measured by a sensor interface of the measuring circuit. The measuring circuit sensor interface may be realised, for example, on the basis of an electronic interface such as that described in the article by Messrs H. Leuthold and F. Rudolph, which appeared in the journal entitled, “Sensors and Actuators” A21-A23 (1990), pages 278 to 281. A piezo-resistive accelerometer can also be used.

This sensor interface supplies a measuring signal for the physical parameter (acceleration) to means for pre-processing the measuring signal so that the means supply a digital output signal S_{D} relating to the parameter measurement. This output signal may be exploited directly or via integrated SIM circuit 11, to control an action or function of a portable instrument, such as a mobile telephone. This allows a rapid command to be performed in the telephone.

In the preferred case of a movement sensor, for measuring acceleration or shock, a command can be provided directly to the portable electronic instrument or via the integrated circuit of said card. This command relating to the detected movement can enable the instrument to recognise actions or functions to be performed that are pre-programmed by the user. One could envisage executing a specific function in the instrument via a single shock or impulse imparted to the chip card or several successive impulses imparted to the chip card within a defined period of time.

This digital output signal S_{D} can be stored in a measuring circuit memory or preferably in a dedicated register of the memory unit of integrated SIM circuit 11. Reading this stored digital signal depends upon the user and remains flexible over time. Said stored output signal might thus be required to be read at any time. This memory unit can also store measuring circuit configuration parameters, personal to the chip card user, and/or different successive measuring circuit output signals. In this way, a number of personal data or configurations are stored in the memory of measuring circuit 10 or in the memory unit of SIM circuit 11. The chip card can thus be placed in any other portable instrument, i.e. in any other mobile telephone without having to repeat all the operations of personal command or data programming or storage.

After the sensor interface, the sensor measuring circuit may include, as pre-processing means, another analogue signal processing unit, an analogue-digital converter, digital signal control and processing unit, an oscillator and a regulated voltage regulator for powering the electronic components of the measuring circuit at a regulated voltage. All of these measuring circuit components are integrated in the electronic module. The digital output signal S_{D} can thus be provided by the control and processing unit so that it can be stored in a dedicated register in the SIM circuit memory unit. This arrangement of the electronic components of the measuring circuit is described, in particular, in CH Patent Application No. 01431/07 by the same Applicant, which is incorporated herein by reference.

In one embodiment of the chip card, the measuring circuit, without the movement sensor, is made in a second integrated circuit with all of the aforecited electronic components. This second integrated circuit and the movement sensor are mounted inside the electronic module case, and electrically connected to external connection terminals of the electronic module so they can be electrically connected to the first integrated circuit of the chip card. The first integrated circuit and the electronic module can be placed side by side in the insulating material of the chip card. The MEMS sensor, which is electrically connected to the measuring circuit sensor interface, can be mounted on the second integrated circuit or placed in the same plane as the second integrated circuit in the electronic module case.

One could also envisage the chip card also including its own electric power means (stand-alone mode). A solar cell or an electric energy accumulator or an RFID device may form these electric power means. Several integrated circuits may also be mounted in the same chip card or several measuring circuits with sensors for measuring other physical parameters, such as pressure and/or temperature.

FIGS. 3a and 3b show in a simplified manner the integrated SIM circuit 11 and electronic module 10 containing the measuring circuit mounted in one part of chip card 1 according to the invention.

Electronic module 10, as explained above, includes in a conventional plastic MLF case, a measuring circuit with a movement sensor, which is mounted on a copper lead frame. The measuring circuit is made up of a sensor interface and the movement sensor, which define, for example, a single axis or triaxial accelerometer, or a pedometer. The sensor interface forms part of a second integrated circuit, which also integrates means for pre-processing the measuring signal so that the means provide a digital output signal S_{D} relating to the parameter measurement. These measuring signal pre-processing means have an analogue signal processing unit, an analogue-digital converter, a digital signal control and processing unit, an oscillator and a regulated voltage regulator. The measuring circuit is electrically connected through one wall of the module case to external connection terminals (not shown), which are arranged on an external surface of the module case.

Just like the first integrated SIM circuit 11, electronic module 10 is mounted on a first surface of a printed circuit board 14. This printed circuit board may be made of FR4, ceramics or silicon. The connection terminals of the module can be directly connected on connection pads provided on the first surface of plate 14 for that purpose. Either a flip chip technique or a brazing technique can be used to do this. However, the connection terminals of the electronic module can also be electrically connected across the printed circuit board by means of metal connecting wires 21 across accessible connection pads on said printed circuit board 14. The integrated SIM circuit 11 includes a set of contact pads 20, some of which are electrically connected across connection pads of printed circuit board 14 by metal wires 21. These metal wires may be gold, aluminium or copper wires.

The assembly including printed circuit board 14 on which the electronic module 10 and integrated SIM circuit 11 are mounted, is mounted on a first surface of a connecting substrate 13, which may be a flexible film generally used in SIM chip cards. This flexible film may be made with a glass fibre charged epoxy resin carrying metal conductive paths made of gold, copper and nickel.

A connecting frame 15 surrounds the assembly mounted on connecting substrate 13. Connecting frame 15 secured to flexible substrate 13 defines a cell for mounting the assembly, which includes printed circuit board 14 with module 10 and integrated circuit 11. On a first surface of this connecting frame 15, there are connection pads 12 connected through the connecting frame to electric contacts belonging to the zone of electric contacts accessible from outside the card for connection in an electronic instrument. The electric contact zone (not shown) is arranged on a second surface of connecting substrate 13 opposite the first assembling surface of the assembly.

These connection pads 12 of the connecting frame are 8 in number for connection to two electric contacts V_{CC} and GND of the contact zone, to an electric contact RST for receiving a Reset signal, to an electric contact V_{PP} for receiving a voltage programming signal from the memory unit, to an electric contact CLOCK for receiving or supplying a clock signal and to an electric contact I/O for receiving or transferring data or commands. With the exception of two connection pads represented by N/C, connection pads 12 are connected by metal wires 22 either across connection pads of the printed circuit board 14 or directly across contact pads 20 of the integrated SIM circuit 11 as shown.

For industrial production, it is advantageous for electronic module 10 and integrated SIM circuit 11 to be already mounted on printed circuit board 14. Afterwards, this assembly is mounted on flexible substrate 13 and electrically connected to connection pads 12 of connecting frame 15 in order to be compatible with mass production. Once all of the electronic components are mounted and their electric connections have been made, all of these elements are enclosed or encapsulated in a conventional manner in an insulating material 16 forming said chip card 1 which has a thickness of the order of 0.7 mm for example.

From the description that has just been given, those skilled in the art can devise several variants of the chip card without departing from the scope of the invention defined by the claims. In the case of a chip card in the form of a memory card, the electric contact zone can be on one edge of said card while part of the electric contacts are situated on at least one main surface of the card. The connecting means for said chip card may also be a wireless connecting device, such as an RFID device or a light transmission/reception device. Inside the opaque material enclosing the integrated circuit(s), there may be a housing for the sensor depending upon the type of physical parameter to be measured. The measuring circuit could have been made in the integrated SIM circuit, housed in the electronic module, with the MEMS sensor connected to the measuring circuit sensor interface. The MEMS sensor can be mounted on the integrated circuit, which includes the measuring circuit and the SIM circuit. A temperature and/or pressure sensor that works alternately with the measuring circuit containing the movement sensor can also be provided in the chip card.

What is claimed is:

1. A SIM type chip card, which includes at least one integrated circuit fitted with a memory unit, in which personal data and/or at least one chip card identification code and/or configuration parameters can be stored, wherein said integrated circuit is enclosed in an insulating material forming said card, the card also including connecting means for communicating with an electronic instrument in the form of a mobile telephone, said connecting means being electrically connected to corresponding contact pads of the integrated circuit, the chip card further including a measuring circuit with a sensor for measuring a physical parameter so as to provide at least one output signal relating to the measurement of the physical parameter, said measuring circuit with a sensor being arranged in a rigid case to define an electronic module, which is enclosed in the insulating material forming said chip card, wherein the measuring circuit includes a movement sensor, housed in a large enough space inside the case to allow detection of a shock or to measure an acceleration, and a sensor interface connected to the sensor to supply a physical parameter measurement signal, the measuring circuit being electrically connected through the module case to external connection terminals on the case, and wherein the electronic module is electrically connected by the external connection terminals to the first integrated circuit of the chip card, the electronic module and the first integrated circuit being placed side by side in the insulating material of the chip card on a first surface of a printed circuit board.

2. The chip card according to claim 1, wherein the measuring circuit in the module case also includes means for pre-processing the measuring signal provided by the sensor interface, such that the pre-processing means supply an output signal relating to the parameter measurement which can be used to control an action or function of the electronic instrument.

3. The chip card according to claim 1, wherein the connecting means include a wireless connecting device and/or a zone of accessible electric contacts on at least one surface of the card that will come into contact with complementary contact terminals of an electronic instrument in which said chip card can be placed, wherein said electric contacts are electrically connected to corresponding contact pads of the integrated circuit, and wherein the measuring circuit with a sensor for measuring a physical parameter can supply at least one output signal relating to the measurement of the physical parameter via an electric connection through the case of the electronic module and via the wireless connecting device and/or via one of the electric contacts of the contact zone.

4. The chip card according to claim 1, wherein the measuring circuit with a sensor is a triaxial accelerometer, which includes a micro electro-mechanical element, electrically connected to a sensor interface of the measuring circuit.

5. The chip card according to claim 1, wherein there is sufficient space for the movement sensor and the measuring circuit sensor interface inside the electronic module case to allow said sensor to detect a shock or to measure an acceleration.

6. The chip card according to claim 1, wherein the sensor interface of the measuring circuit is provided on the basis of a single or several successive accelerations or shocks of said chip card, to supply a signal controlling the execution of a pre-programmed action or function in the electronic instrument.

7. The chip card according to claim 1, wherein at least one dedicated register in the integrated circuit memory unit is provided for storing the output signal that relates to the parameter measurement of the measuring circuit and is supplied to the integrated circuit through the case of the electronic module.

8. The chip card according to claim 1, wherein the measuring circuit, without the sensor, is made in a second integrated circuit and connected to the movement sensor in the electronic module case.

9. The chip card according to claim 8, wherein a second surface of the printed circuit board is mounted on an inner surface of a connecting substrate, wherein a connecting frame is secured to the inner surface of the connecting substrate and surrounds the printed circuit board, and wherein the external surface of the connecting substrate has an accessible electric contact zone that comes into contact with complementary contact terminals of an electronic instrument in which said chip card can be placed, wherein the contact zone is electrically connected to the first integrated circuit and to the electronic module.

10. The chip card according to claim 1, wherein it includes means for electrically powering the components of the chip card, such as a solar cell or an electric energy accumulator or an RFID device for picking up radio-frequency signals.

11. A method of manufacturing a chip card according to claim 1, wherein the method includes the steps consisting in:
mounting and electrically connecting the electronic module, whose case contains the measuring circuit with a movement sensor, and the integrated circuit of the card on a first surface of a printed circuit board, and
encapsulating the electronic module and the integrated circuit in a layer of insulating material that forms said card while allowing means for connecting the chip card, which are electrically connected at least to the integrated circuit, to communicate with an electronic instrument.

12. The method of manufacturing a chip card according to claim 11, wherein, prior to the operation of encapsulating the electronic module and the integrated circuit in the insulating material, a second surface of the printed circuit board is secured to an inner surface of a connecting substrate, an outer surface of which includes a zone of accessible electric contacts that come into contact with complementary contact terminals of an electronic instrument.

13. The method of manufacturing a chip card according to claim 12, wherein, prior to or after mounting the electronic module and the integrated circuit on the first surface of the printed circuit board, it includes the steps of:
securing a connecting frame to the inner surface of the flexible connecting substrate so as to define a cell for receiving the printed circuit board, and
securing the second surface of the printed circuit board, which is fixed to the inner surface of the connecting substrate inside the cell defined by the connecting frame.
